(19) United States
(12) Patent Application Publication
(10) Pub. No.: US 2023/0217769 A1
(43) Pub. Date: Jul. 6, 2023

(54) ELECTRONIC DEVICE

(71) Applicant: InnoLux Corporation, Miao-Li County (TW)

(72) Inventors: Jia-Yuan CHEN, Miao-Li County (TW); Tsung-Han TSAI, Miao-Li County (TW)

(73) Assignee: InnoLux Corporation, Miao-Li County (TW)

(21) Appl. No.: 17/994,003

(22) Filed: Nov. 25, 2022

(30) Foreign Application Priority Data
Dec. 31, 2021 (CN) 202111670289.4

(51) Int. Cl. H01L 35/24

(52) U.S. Cl. CPC H01L 27/322; H01L 51/5284

(57) ABSTRACT

An electronic device is provided and includes a substrate, a first light emitting unit, a first color filter, a first wavelength conversion layer, and a second color filter. The first light emitting unit is disposed on the substrate and configured to emit a first light, the first color filter is disposed on the first light emitting unit, and the first wavelength conversion layer is disposed on the first color filter. The second color filter is disposed on the first wavelength conversion layer. The first light passes through the first color filter, the first wavelength conversion layer converts the first light into a second light, and the second light passes through the second color filter.

### BACKGROUND OF THE DISCLOSURE

### 1. Field of the Disclosure

The present disclosure relates to an electronic device and more particularly to an electronic device providing a function of reducing reflection of ambient light.

### 2. Description of the Prior Art

Since the convenience of electronic devices is continuously improved, they become an indispensable tool in people's lives. However, when the electronic device is used outdoors, quality of images displayed by the electronic device is reduced by ambient light, such that the user is not easy to view the image. Although anti-reflection films or anti-reflection structures have been developed to be installed in the conventional electronic devices, there still have problems of poor light extraction efficiency and bad anti-reflection effect in need of solving.

### SUMMARY OF THE DISCLOSURE

According to some embodiments, the present disclosure provides an electronic device including a substrate, a first light emitting unit, a first color filter, a first wavelength conversion layer, and a second color filter. The first light emitting unit is disposed on the substrate and configured to emit a first light, the first color filter is disposed on the first light emitting unit, and the first wavelength conversion layer is disposed on the first color filter. The second color filter is disposed on the first wavelength conversion layer. The first light passes through the first color filter, the first wavelength conversion layer converts the first light into a second light, and the second light passes through the second color filter.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a schematic cross-sectional view illustrating an electronic device according to a first embodiment of the present disclosure.

FIG. 2 is a schematic cross-sectional view illustrating an electronic device according to a second embodiment of the present disclosure.

FIG. 3 is a schematic cross-sectional view illustrating an electronic device according to a third embodiment of the present disclosure.

FIG. 4 is a schematic top view illustrating a part of an electronic device according to a fourth embodiment of the present disclosure.

FIG. 5 is a schematic top view illustrating a part of an electronic device according to a fifth embodiment of the present disclosure.

FIG. 6 is a schematic cross-sectional view illustrating apart of an electronic device according to a sixth embodiment of the present disclosure.

FIG. 7 is a schematic cross-sectional view illustrating an electronic device according to a seventh embodiment of the present disclosure.

FIG. 8 is a schematic cross-sectional view illustrating an electronic device according to a variant embodiment of the seventh embodiment of the present disclosure.

FIG. 9 is a schematic cross-sectional view illustrating an electronic device according to an eighth embodiment of the present disclosure.

FIG. 10 is a schematic cross-sectional view illustrating an electronic device according to a ninth embodiment of the present disclosure.

FIG. 11 is a schematic cross-sectional view illustrating an electronic device according to a tenth embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and elements therein may not be drawn to scale. The numbers and sizes of the elements in the drawings are just illustrative and are not intended to limit the scope of the present disclosure.

Certain terms are used throughout the specification and the appended claims of the present disclosure to refer to specific elements. Those skilled in the art should understand that electronic equipment manufacturers may refer to an element by different names, and this document does not intend to distinguish between elements that differ in name but not function. In the following description and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the elements of the claims. It does not mean that the element has any previous ordinal numbers, nor does it represent the order of a certain element and another element, or the sequence in a manufacturing method. These ordinal numbers are just used to make a claimed element with a certain name be clearly distinguishable from another claimed element with the same name. Thus, a first element mentioned in the specification may be called a second element.

Spatially relative terms, such as “above”, “on”, “beneath”, “below”, “under”, “left”, “right”, “before”, “front”, “after”, “behind” and the like, used in the following embodiments just refer to the directions in the drawings and are not intended to limit the present disclosure. It may be understood that the elements in the drawings may be disposed in any kind of formation known by those skilled in the related art to describe or illustrate the elements in a certain way. Furthermore, when one element is mentioned to overlap another element, it may be understood that the element may partially or completely overlap the another element.

In addition, when one element or layer is “on” or “above” another element or layer, it may be understood that the element or layer is directly on the another element or layer, and alternatively, another element or layer may be between the one element or layer and the another element or layer (indirectly). On the contrary, when the element or layer is “directly on” the another element or layer, there is no intervening element or layer between the element or layer and the another element or layer.

As disclosed herein, when one element is referred to as being “electrically connected to” or “coupled to” another element, it will be understood that intervening elements may be between the element and the another element and electrically connect the element to the another element, and alternatively, the element may be directly electrically connected to the another element without intervening elements existing between them. If one element is referred to as being “directly electrically connected to” or “directly coupled to” another element, there are no intervening elements present between them.

As disclosed herein, the terms “approximately”, “essentially”, “about”, “substantially”, and “same” generally mean within 10%, 5%, 3%, 2%, 1%, or 0.5% of the reported numerical value or range. The quantity disclosed herein is an approximate quantity, that is, without a specific description of “approximately”, “essentially”, “about”, “substantially”, and “same”, the quantity may still include the meaning of “approximately”, “essentially”, “about”, “substantially”, and “same”.

It should be understood that according to the following embodiments, features of different embodiments may be replaced, recombined or mixed to constitute other embodiments without departing from the spirit of the present disclosure. The features of various embodiments may be mixed arbitrarily and used in different embodiments without departing from the spirit of the present disclosure or conflicting.

In the present disclosure, the length, width, thickness, height, area, or distance or gap between elements may be measured by using an optical microscope (OM), a scanning electron microscope (SEM), a thin film thickness and surface profile gauge (α-step), an ellipsometer or other approaches, but not limited thereto. According to some embodiments, a cross-sectional structure image of an element to be measured may be obtained by the SEM, and the length, width, thickness, height, or area of each element, or distance or gap between elements may be measured, but not limited thereto. Furthermore, any two values or directions for comparison may have a certain error between them.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a special definition in the embodiments of the present disclosure.

In the present disclosure, the electronic device may have a display function and may optionally include an optical sensing, image detecting, touching sensing, or antenna function, other suitable functions or any combination thereof, but not limited thereto. The electronic device may be bendable, flexible or stretchable electronic device. In some embodiments, the electronic device may include tiled device, but not limited thereto. The electronic device may include liquid crystal molecule, light emitting diode (LED), quantum dot material, a fluorescent material, a phosphor material, other suitable materials, or any combination thereof, but not limited thereto. The LED may for example include organic light emitting diode (OLED), micro light emitting diode (micro-LED) or mini light emitting diode (mini-LED), or quantum dot light emitting diode (e.g., QLED or QDLED), but not limited thereto. In addition, the electronic device may be a color display device, a single color display device, or a grayscale display device. The appearance of the electronic device may be rectangular, circular, polygonal, a shape with curved edges, curved or other suitable shapes, but not limited thereto. The electronic device may optionally have peripheral systems such as a driving system, a control system, a light source system, a shelf system, etc. The following description takes the electronic device as the display device for illustration, but not limited thereto.

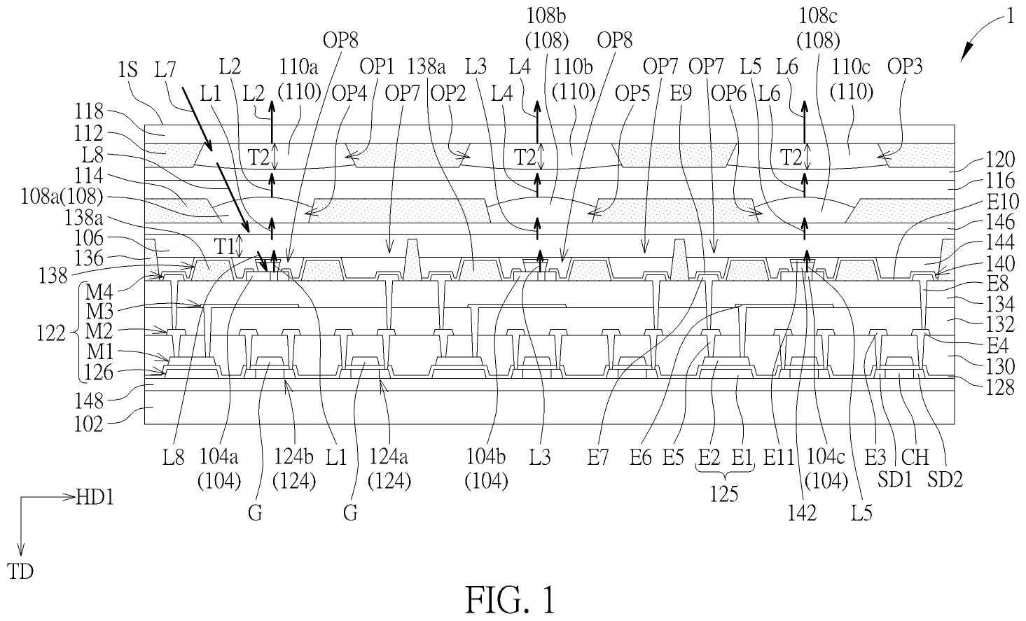

Refer to FIG. 1, which is a schematic cross-sectional view illustrating an electronic device according to a first embodiment of the present disclosure. In order to clearly show main features of the present disclosure, the drawings in the following description show the cross-sectional views of a part of the electronic device, but not limited thereto. As shown in FIG. 1, the electronic device 1 may include a substrate 102, at least one light emitting unit 104, a color filter 106, at least one wavelength conversion layer 108, and at least one color filter 110. The substrate 102 may include, for example, a flexible substrate or a non-flexible substrate. A material of the substrate 102 may include, for example, glass, ceramic, quartz, sapphire, acrylic, polyimide (PI), polyethylene terephthalate (PET), polycarbonate (PC), other suitable materials or any combination thereof, but not limited thereto. The numbers of the light emitting units 104, the wavelength conversion layers 108 and the color filters 110 in the following description may respectively be plural as an example, but not limited thereto.

One of the light emitting units 104 may be disposed on the substrate 102 and configured to generate a first light (e.g., light L1, light L3 or light L5). The light emitting unit 104 may include, for example, an inorganic LED, an organic LED, a mini LED, a micro LED, a quantum dot LED, a nanowire LED, a bar type LED, a nanorod LED, or other suitable light emitting elements. In the embodiment of FIG. 1, the light emitting unit 104 may include a rod-shaped LED, and the rod-shaped LED may include a P-type semiconductor layer, a light emitting layer, and an N-type semiconductor layer arranged along a horizontal direction HD1 perpendicular to a top-view direction TD, but not limited thereto. The top view direction TD of the electronic device 1 may be, for example, a direction perpendicular to an upper surface of the substrate 102, but not limited thereto. In addition, in the embodiment of FIG. 1, the light emitting unit 104 may for example include an LED or a light emitting element, but not limited thereto. In some embodiments, the light emitting unit 104 may include a plurality of LEDs or light emitting elements. In some embodiments, the light emitting unit 104 may further include a fluorescent material, a phosphor material, quantum dot particles, other suitable materials, or any combination thereof, but not limited thereto.

In the embodiment of FIG. 1, the light emitting units 104 may include a light emitting unit 104a, a light emitting unit 104b, and a light emitting unit 104c as an example for illustration, but not limited thereto. The light emitting unit 104a, the light emitting unit 104b, and the light emitting unit 104c may be configured to generate the light L1, the light L3, and the light L5, respectively. For example, the light emitting unit 104a, the light emitting unit 104b, and the light emitting unit 104c may be the same as each other, and the light L1, the light L3, and the light L5 may have the same color, such as blue light, light of color with a wavelength less than that of blue light, white light, or light of other suitable colors, but not limited thereto. In some embodiments, at least two of the light emitting unit 104a, the light emitting unit 104b, and the light emitting unit 104c may be the same, and at least two of the light L1, the light L3, and the light L5 may have the same color. In some embodiments, the light emitting unit 104a, the light emitting unit 104b and the light emitting unit 104c may be different from each other, and the light L1, the light L3 and the light L5 may have different colors, but not limited thereto.

The color filter 106 may be disposed on the light emitting units 104 to allow first light with a specific wavelength to pass through, and for example, the light L1, the light L3 and the light L5 may pass through the color filter 106. A color of the color filter 106 may be, for example, the same as or close to the color of the light L1, the light L3, and the light L5, so as to allow the light L1, the light L3 and the light L5 to pass through and block (e.g., absorb or reflect) at least a portion of light of a color different from the color of the light L1, the light L3 and the light L5. The color filter 106 may be, for example, a blue filter, a filter that allows light with a wavelength less than that of blue light to pass through, or other suitable filters.

One of the wavelength conversion layers 108 may be disposed on the color filter 106 and may convert the first light into a second light (e.g., light L2, light L4, or light L6). In other words, the wavelength conversion layer 108 may generate the second light by absorbing the first light. In some embodiments, a wavelength of the first light corresponding to a maximum peak intensity may be less than a wavelength of the second light corresponding to a maximum peak intensity, for example, the wavelength of the first light corresponding to the maximum peak intensity is about 450 nanometers (nm), The wavelength of the second light corresponding to the maximum peak intensity is about 630 nm. In the embodiment of FIG. 1, the wavelength conversion layers 108 may include a wavelength conversion layer 108a, a wavelength conversion layer 108b, and a wavelength conversion layer 108c as an example for illustration, but not limited thereto. The wavelength conversion layer 108a may be disposed on the light emitting unit 104a, and the color filter 106 may be disposed between the wavelength conversion layer 108a and the light emitting unit 104a, so that the wavelength conversion layer 108a may convert the light L1 passing through the color filter 106 into the light L2. The wavelength conversion layer 108b may be disposed on the light emitting unit 104b, and the color filter 106 may be disposed between the wavelength conversion layer 108b and the light emitting unit 104b, so that the wavelength conversion layer 108b may convert the light L3 passing through the color filter 106 into the light L4. The wavelength conversion layer 108c may be disposed on the light emitting unit 104c, and the color filter 106 may be disposed between the wavelength conversion layer 108c and the light emitting unit 104c, so that the wavelength conversion layer 108c may convert the light L5 passing through the color filter 106 into the light L6. In some embodiments, the wavelengths of the light L1, the light L3 and the light L5 corresponding to the maximum peak intensities may be respectively less than the wavelengths of the light L2, the light L4 and the light L6 corresponding to the maximum peak intensities. In the embodiment of FIG. 1, the light L2, the light L4 and the light L6 may have different colors, and they may for example be mixed into white light. The light L2, the light L4 and the light L6 may, for example, be red light, green light and blue light, respectively, but not limited thereto. In some embodiments, the wavelength conversion layer 108a, the wavelength conversion layer 108b, and the wavelength conversion layer 108c may include, for example, a fluorescent material, a phosphor material, quantum dot particles, or other light conversion materials capable of converting the color of light.

One of the color filters 110 may be disposed on one of the wavelength conversion layers 108, and the second light (e.g., the light L2, the light L4 or the light L6) may pass through the color filter 110 and then be emitted from the light emitting surface 1S of the electronic device 1. In the embodiment of FIG. 1, the color filters 110 includes a color filter 110a, a color filter 110b and a color filter 110c as an example for illustration, but not limited thereto. The color filter 110a may be disposed on the wavelength conversion layer 108a, and a color of the color filter 110a may be, for example, the same as or close to the color of the light L2, so as to allow the light L2 to pass through and block (absorb or reflect) at least a portion of light with a color different from the color of the light L2. The color filter 110b may be disposed on the wavelength conversion layer 108b, and a color of the color filter 110b may be the same as or close to the color of the light L4, for example, to allow the light L4 to pass through and block (absorb or reflect) at least a portion of light with a color different from the color of the light L4. The color filter 110c may be disposed on the wavelength conversion layer 108c, and a color of the color filter 110c may be, for example, the same as or close to the color of the light L6, so as to allow the light L6 to pass through and block (absorb or reflect) at least a portion of light with a color different from the color of the light L6. After passing through the color filter 110a, the color filter 110b and the color filter 110c, the light L2, the light L4 and the light L6 may be emitted from the light emitting surface 1S of the electronic device 1, so as to be respectively used as light generated by different sub-pixels of a pixel (or light generated by different pixels) in the electronic device 1. Through the color filter 110a, the color filter 110b and the color filter 110c, the colors of the light L2, the light L4 and the light L6 emitted from the light emitting surface 1S may be purified to meet the usage requirements. For example, the color filter 110a, the color filter 110b, and the color filter 110c may be a red filter, a green filter, and a blue filter, respectively, but not limited thereto. In some embodiments, the colors of the color filter 110a, the color filter 110b, and the color filter 110c may be adjusted according to the colors of the light L2, the light L4, and the light L6, respectively, but not limited thereto. In some embodiments, the color filter 110c may for example have the same color as the color filter 106, but not limited thereto. In some embodiments, when the colors of the light L5 and the light L6 are the same, the electronic device 1 may not include the wavelength conversion layer 108c and the color filter 110c, or the electronic device 1 may include the color filter 110c but not include the wavelength conversion layer 108c, but not limited thereto.

It should be noted that, in the present disclosure, light that “passes through” the color filter may refer to that a transmittance of the color filter may range from 60% to 99% or from 70% to 95% for the passing light, but not limited thereto. For example, for complying with the requirement of high color saturation, the color filter 110a may have a transmittance of 92% for the light L2 with a wavelength of about 630 nm, the color filter 110b may have a transmittance of 77% for the light L4 with a wavelength of about 540 nm, and the color filter 110c may have a transmittance of 72% for light L6 with a wavelength of about 450 nm. Alternatively, for complying with the requirement of high transmittance, the color filter 110a may have a transmittance of 97% for the light L2 with a wavelength of about 630 nm, the color filter 110b may have a transmittance of 87% for the light L4 with a wavelength of about 540 nm, and the color filter 110c may have a transmittance of 77% for the light L6 with a wavelength of about 450 nm, but not limited thereto. In addition, in the present disclosure, the color filter 106 and the color filters 110 are not able to convert the incident light into light of a color different from the incident light (or generate light of a color different from the incident light by absorbing the incident light), that is, functions of the color filter 106 and the color filters 110 are different from that of the wavelength conversion layers 108. For example, the material of the color filter 106 and/or the materials of the color filters 110 may include photoresist materials, ink materials, pigments, dyes, distributed Bragg reflectors (DBR), other suitable filter materials, or a combination of any two thereof. In some embodiments, according to the materials, the color filters 110 may be formed by, for example, a coating and patterning process, an inkjet printing process, a dripping process, or other suitable processes. In the present disclosure, the material of the color filter 106 and/or the materials of the color filters 110 may absorb light of different colors, but not limited thereto.

It should be noted that, since the color of the color filter 110a (or the color filter 110b) may be different from the color of the color filter 106, the color filter 110a (or the color filter 110b) and the color filter 106 may absorb light of different colors respectively and have complementary light absorption characteristics, which may reduce the interference of the ambient light on the images displayed by the electronic device 1. As shown in FIG. 1, when the ambient light (e.g., light L7) enters the electronic device 1 from the light emitting surface 1S, it will first be absorbed by the color filter 110a (or the color filter 110b) to become light L8 with the same color as the color filter 110a (or the color filter 110b) and be directed to the wavelength conversion layer 108a (or the wavelength conversion layer 108b), and most of the light L8 may pass through the wavelength conversion layer 108a (or the wavelength conversion layer 108b) and be directed to the color filter 106. Since the color of the color filter 106 is different from the color of the color filter 110a (or the color filter 110b), most of the light L8 passing through the wavelength conversion layer 108a (or the wavelength conversion layer 108b) may be absorbed by the color filter 106, so that the intensity of the light L8 reflected by the circuit layer (such as the circuit layer mentioned below) toward the light emitting surface 1S may be significantly reduced, thereby mitigating the interference of the ambient light on the electronic device 1 and improving image quality. In addition, since one of the wavelength conversion layers 108 may be disposed between the color filter 106 and one of the color filters 110, the first light that is capable of passing through the color filter 106 is converted into the second light that is capable of passing through one of the color filter 110, such that the light emitting surface 1S of the electronic device 1 may emit the second light of the color different from the first light.

In some embodiments, the thickness T1 of the color filter 106 may be greater than the thickness T2 of at least one of the color filter 110a, the color filter 110b and the color filter 110c, which may increase the intensities of the light L1, the light L3 and the light L5 passing through the color filter 106, thereby enhancing the intensities of the light L2, the light L4 and the light L6 emitted from the light emitting surface 1S of the electronic device 1 while reducing the reflection of the ambient light (e.g., the light L7). For example, the thickness T1 of the color filter 106 may range to be as small as about one third of the thickness T2 of at least one of the color filter 110a, the color filter 110b, and the color filter 110c (thickness T2>thickness T1≥⅓×thickness T2). The thickness T1 of the color filter 106 may also be as small as about half of the thickness T2 of at least one of the color filter 110a, the color filter 110b and the color filter 110c (thickness T2>thickness T1≥½×thickness T2). In some embodiments, the thickness T1 of the color filter 106 may be, for example, 0.2 micrometers (μm) to 1.5 μm, and the thickness T2 of at least one of the color filter 110a, the color filter 110b and the color filter 110c may be, for example, 1 μm to 3 μm, but not limited thereto. In the present disclosure, the thicknesses of the color filter 110a, the color filter 110b, and the color filter 110c may be, for example, the maximum thicknesses in the top view direction TD, respectively. In some embodiments, the thicknesses T2 of any two of the color filter 110a, the color filter 110b and the color filter 110c may be the same as or different from each other, so as to adjust the intensities of the light L2, the light L4 and the light L6 to meet the requirements of the displayed image.

As shown in FIG. 1, the electronic device 1 may further include a light shielding layer 112 disposed on the color filter 106, and the light shielding layer 112 may have an opening OP1 in which the color filter 110a may be disposed, an opening OP2 in which the color filter 110b may be disposed, and an opening OP3 in which the color filter 110c may be disposed. In other words, the light shielding layer 112 may be disposed between any two adjacent color filters 110, which may reduce or prevent light, for example, the light L2 passing through the color filter 110a, the light L4 passing through the color filter 110b, the light passing through the color filter 110b, etc., from mixing.

In the top view direction TD (or a top view) of the electronic device 1, an area of the opening OP1 may be the same as or different from an area of the opening OP2, so that in the top view direction TD, the area of the color filter 110a may be the same as or different from that of the color filter 110b. In some embodiments, the intensity of light L2 passing through the color filter 110a and the intensity of light L4 passing through the color filter 110b may be adjusted by changing the area of the opening OP1 and the area of the opening OP2, but not limited thereto. In some embodiments, the area of the opening OP3 may be the same as or different from the area of the opening OP1 and/or the area of the opening OP2. In the present disclosure, “the area of the opening” may refer to an area of a region surrounded by the inner edge of the opening when viewed along the top view direction TD.

As shown in FIG. 1, in some embodiments, the electronic device 1 may further include a substrate 118 and an insulating layer 120, in which the light shielding layer 112, the color filter 110a, the color filter 110b and the color filter 110c may be disposed on the substrate 118 and the insulating layer 120, and the insulating layer 120 may be disposed between the light shielding layer 112 and the light shielding layer 114. The substrate 118 may include, for example, a flexible substrate or a non-flexible substrate. A material of the substrate 118 may include, for example, glass, ceramic, quartz, sapphire, acrylic, PI, PET, PC, other suitable materials, or any combination thereof, but not limited thereto. In the embodiment of FIG. 1, the light shielding layer 112 and the color filters 110 may, for example, be formed on the substrate 118, and then the insulating layer 120 is formed on the light shielding layer 112 and the color filter 110. In such case, the insulating layer 120 may be used as an encapsulation layer to protect the light shielding layer 112 and the color filters 110. A material of the insulating layer 120 may include, for example, resin, perfluoroalkoxy alkanes (PFA), epoxy resin, PI, or other suitable insulating materials, but not limited thereto. In some embodiments, when the electronic device 1 does not include the color filter 110c, the insulating layer 120 may for example be disposed in the opening OP3. The method of forming the light shielding layer 112 and the color filters 110 in the present disclosure is not limited to the mentioned above. In some embodiments, the light shielding layer 112 and the color filters 110 may be formed on the wavelength conversion layers 108, but not limited thereto. In some embodiments, the electronic device 1 may optionally not include the insulating layer 120.

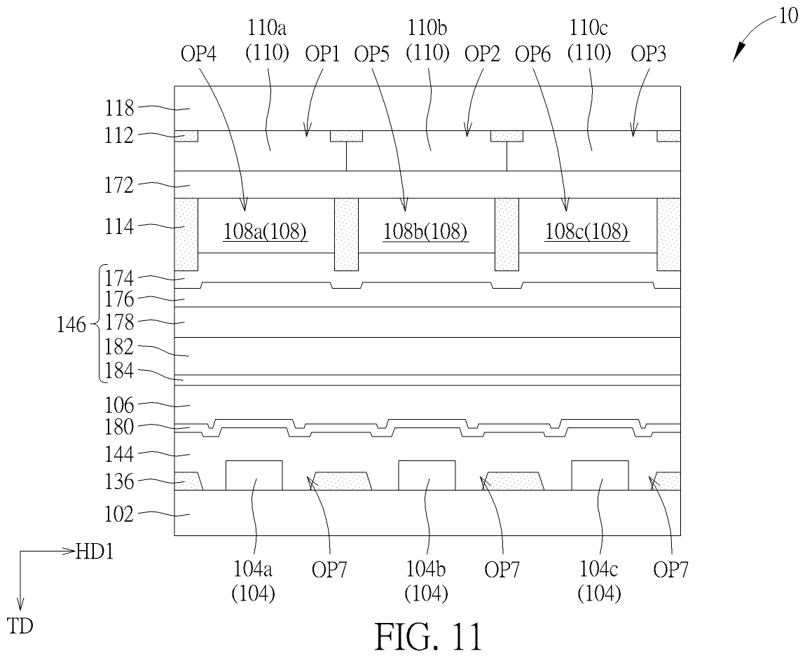

As shown in FIG. 1, the electronic device 1 may include a light shielding layer 114 disposed between the light shielding layer 112 and the color filter 106. The light shielding layer 114 may have an opening OP4, an opening OP5, and an opening OP6 overlapped with the opening OP1, the opening OP2 and the opening OP3 respectively in the top view direction TD (or the top view) of the electronic device 1, in which the wavelength conversion layer 108a, the wavelength conversion layer 108b and the wavelength conversion layer 108c may be respectively disposed in the opening OP4, the opening OP5 and the opening OP6. In some embodiments, the electronic device 1 may optionally further include an insulating layer 116 that may be disposed on the light shielding layer 114 and the wavelength conversion layer 108. In this case, the insulating layer 116 may be, for example, an encapsulation layer that may be used to protect the light shielding layer 114 and the wavelength conversion layer 108, but not limited thereto. In some embodiments, the electronic device 1 may optionally include an adhesive layer (not shown) disposed between the insulating layer 120 and the insulating layer 116 for bonding the insulating layer 120 to the insulating layer 116, but not limited thereto. In some embodiments, when the light shielding layer 112 and the color filters 110 are formed on the wavelength conversion layers 108, the electronic device 1 may optionally not include the insulating layer 120 or the insulating layer 116. In some embodiments, the insulating layer 120 or the insulating layer 116 may have a flat upper surface that may help to form the light shielding layer 112 and the color filter 110. In some embodiments, when the electronic device 1 does not include the wavelength conversion layer 108c, the insulating layer 116 may be disposed in the opening OP6. In some embodiments, the insulating layer 120 or the insulating layer 116 may include a functional layer (e.g., a functional layer 172 shown in FIG. 11) that may help to enhance the color purities of the light L2, the light L4 and the light L6 and/or improve light utilization of the light L1, the light L3 and the light L5. A detailed description of the functional layer 172 may refer to the embodiment of FIG. 11.

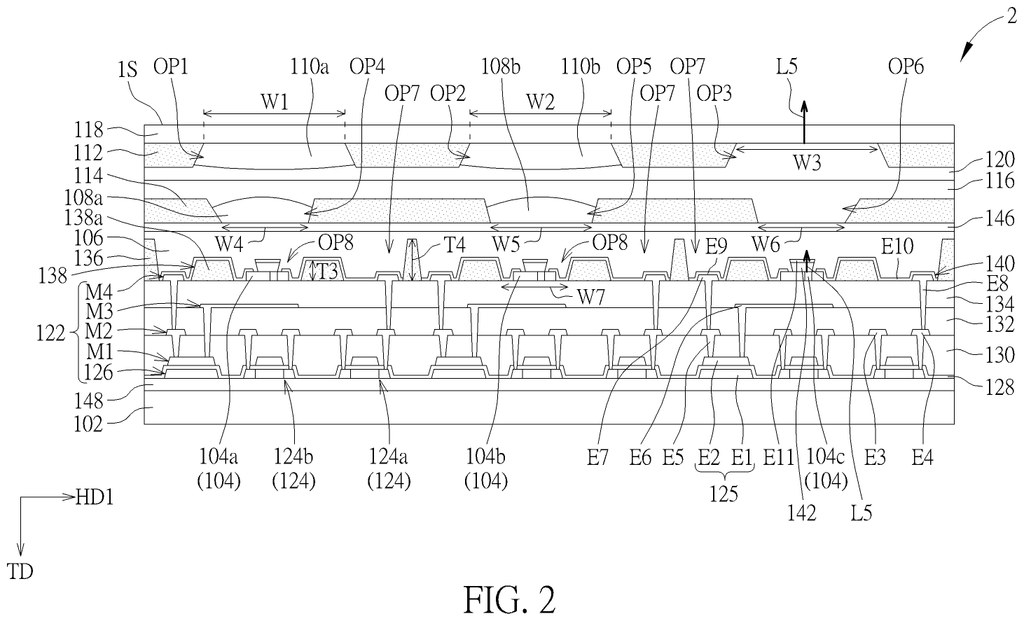

In some embodiments, as viewed along the top view direction TD, a width of the opening OP1 in the horizontal direction HD1 (e.g., a width W1 shown in FIG. 2) may be greater than a width of the opening OP4 in the horizontal direction HD1 (e.g., a width W4 shown in FIG. 2), a width of the opening OP2 in the horizontal direction HD1 (e.g., a width W2 shown in FIG. 2) may be greater than a width of the opening OP5 in the horizontal direction HD1 (e.g., a width W5 shown in FIG. 2), and/or a width of the opening OP3 in the horizontal direction HD1 (e.g., a width W3 shown in FIG. 2) may be greater than a width of the opening OP6 (e.g., a width W6 shown in FIG. 2). Accordingly, brightness of outgoing light of the electronic device 1 may be increased, and/or amount of ambient light (e.g., light L7, etc.) absorbed by the light shielding layer 114 may be increased, thereby reducing the ambient light such as reflected light from the circuit layer, but the present disclosure is not limited thereto. In the present disclosure, the “width” of an opening in a direction may be the minimum width of the opening in this direction.

As shown in FIG. 1, the electronic device 1 may further include a circuit layer 122 disposed between the light emitting unit 104 and the substrate 102. The circuit layer 122 may be used to control switching of the light emitting unit 104a, the light emitting unit 104b and/or the light emitting unit 104c and the brightness of the light L1, the light L3 and the light L5, so that the electronic device 1 may display images. The circuit layer 122 may include a plurality of active elements 124 for driving the corresponding light emitting units 104. In the embodiment of FIG. 1, the circuit layer 122 may include a pixel circuit of 2T1C type (i.e., including two thin film transistors and one capacitor) as an example, but not limited thereto. In some embodiments, the active elements 124 may include a driving element 124a and a switching element 124b. The driving element 124a may be electrically connected between one end of the corresponding light emitting unit 104 and the driving power source to provide a driving current to the light emitting unit through the driving element 124a, and the switching element 124b may be electrically connected to the corresponding driving element 124a for controlling the switching of the drive element 124a. In FIG. 1, one driving element 124a and one switching element 124b may correspond to one light emitting unit 104, but not limited thereto. In some embodiments, the electronic device 1 may further include a plurality of capacitors 125, and one end of one of the capacitors 125 is electrically connected to another end of the corresponding light emitting unit 104.

In some embodiments, the structure of the circuit layer 122 is not limited to that shown in FIG. 1 and may include a plurality of signal lines. The signal lines may include, for example, data lines, scan lines, and power lines. In some embodiments, the circuit layer 122 may further include circuits for controlling the electronic device 1, such as a scan driving circuit and a data driving circuit, but not limited thereto. In some embodiments, the circuit layer 122 may include a pixel circuit of 7T2C type (i.e., including seven thin film transistors and two capacitors), a pixel circuit of 7T3C type (i.e., seven thin film transistors and three capacitors), a pixel circuit of 3T1C type (i.e., three thin film transistors and one capacitor), a pixel circuit of 3T2C type (i.e., three thin film transistors and two capacitors) or other suitable type of pixel circuit architecture.

As shown in FIG. 1, one of the active elements 124 may be, for example, a thin film transistor, but not limited thereto. The active elements 124 shown in FIG. 1 may be top-gate type thin film transistors as an example, and the circuit layer 122 may include a semiconductor layer 126, an insulating layer 128, a metal layer M1, an insulating layer 130, a metal layer M2, an insulating layer 132, a metal layer M3, an insulating layer 134, and a metal layer M4. The semiconductor layer 126 may be disposed on the substrate 102 and include channels CH, source(drain) regions SD1 and drain(source) regions SD2 of the active elements 124 and electrodes E1 of the capacitors 125. One of the source(drain) regions SD1 and the corresponding drain(source) region SD2 may be disposed on two sides of the corresponding channel CH and include, for example, P-type doped or N-type doped semiconductors, but not limited thereto. The insulating layer 128 may be disposed on the semiconductor layer 126 and be regarded as gate insulating layers of the active elements 124, and the metal layer M1 may be disposed on the insulating layer 128 and may, for example, form gates G of the active elements 124, the scan lines and electrodes E2 of the capacitors 125. One of the channels CH may for example overlap the corresponding gate G in the top view direction TD. The insulating layer 130 may be disposed on the insulating layer 128 and the metal layer M1, and the metal layer M2 may be disposed on the insulating layer 130 and include electrodes E3, electrodes E4, the data lines, and connecting electrodes E5. The insulating layer 130 may have through holes, so that one of the electrodes E3 and the corresponding electrode E4 may be electrically connected to one of the source(drain) regions SD1 and the corresponding drain(source) region SD2 through the corresponding through holes, respectively, and one of the connecting electrodes E5 may be electrically connected to the electrode E2 of the corresponding capacitor 125 through the corresponding through hole. The insulating layer 132 may be disposed on the metal layer M2 and the insulating layer 130, and the metal layer M3 may be disposed on the insulating layer 132 and include electrodes E6. The insulating layer 132 and the insulating layer 130 may have through holes, so that one of the electrodes E6 may be electrically connected to the electrode E2 of the corresponding capacitor 125 through the corresponding through hole. The insulating layer 134 may be disposed on the metal layer M3 and the insulating layer 132, and the metal layer M4 may be disposed on the insulating layer 134, and include connecting electrodes E7 and connecting electrodes E8. The insulating layer 134 and the insulating layer 132 may have through holes, so that one of the connecting electrodes E7 may be electrically connected to the corresponding electrode E5 through the corresponding through hole, and one of the connecting electrodes E8 may be electrically connected to the electrode E4 of the corresponding driving element 124a through the corresponding through hole. In the embodiment of FIG. 1, the light emitting unit 104 may be disposed on an upper surface of the insulating layer 134, but not limited thereto. The upper surface of the insulating layer 134 may, for example, be flat, which may improve quality of forming elements (e.g., the light emitting unit 104, the light shielding layer 136 and/or the light shielding layer 138) disposed on the insulating layer 134. In some embodiments, at least one of the insulating layer 130, the insulating layer 132 and the insulating layer 134 may include a single-layer structure or a multi-layer structure. The insulating layer 130, the insulating layer 132 and the insulating layer 134 may include, for example, organic insulating materials and/or inorganic insulating materials.

In some embodiments, structure of one of transistors of the active elements 124 is not limited to the mentioned above and may be a bottom-gate type transistor, or may be changed to a double-gate type transistor or other suitable transistors based on the requirements. Alternatively, the semiconductor layer 126 may include, for example, amorphous silicon, low-temperature polysilicon (LIPS), low-temperature polycrystalline oxide (LTPO), or metal-oxide semiconductor) and be not limited thereto. The number of insulating layers in the electronic device 1 may be changed according to the type of the transistors. In some embodiments, different active elements 124 may include the channels CH of different materials, but not limited thereto.

In the embodiment of FIG. 1, the electronic device 1 may further include a light shielding layer 136, a light shielding layer 138 and a conductive layer 140, in which the light shielding layer 136 and the light shielding layer 138 may be disposed between the circuit layer 122 and the color filter 106. The light shielding layer 136 may have a plurality of openings OP7, and the light shielding layer 138 may include a plurality of blocks 138a respectively disposed in the corresponding openings OP7. Each block 138a may have an opening OP8, each light emitting unit 104 may be disposed in the corresponding opening OP8, and each block 138a of the light shielding layer 138 and the corresponding light emitting unit 104 may be disposed in the corresponding opening OP8. Sidewalls of one of the blocks 138a may, for example, have a function of concentrating the first light generated by the light emitting units 104 to emit toward the light emitting surface 1S of the electronic device 1. In the embodiment of FIG. 1, a width of the opening OP8 in the horizontal direction HD1 (e.g., a width W7 shown in FIG. 2) may be, for example, less than that of the opening OP4, the opening OP5 or the opening OP6 in the horizontal direction HD1 when viewed along the top view direction TD (e.g., the width W4, the width W5, or the width W6 shown in FIG. 2), so as to improve the light utilization of the first light, but not limited thereto. In some embodiments, a height of an upper surface of the light shielding layer 136 may be greater than a height of an upper surface of one of the blocks 138a, and for example, the thickness T4 of the light shielding layer 136 shown in FIG. 2 may be greater than the thickness T3 of each block 138a, but not limited thereto. The “height” herein may be compared with respect to the same horizontal plane parallel to the horizontal direction HD1, for example, with respect to the upper surface of the insulating layer 134, but not limited thereto.

The light shielding layer 136 may be, for example, a pixel defining layer, so that in the top view direction TD, a region of the opening OP7 may be used to define a pixel or a sub-pixel of the electronic device 1, but not limited thereto. In FIG. 1, the color filter 106 may overlap three openings OP7 (i.e., three pixels or three sub-pixels) in the top view direction TD and may be not limited thereto. In some embodiments, the color filter 106 may overlap the openings OP7 corresponding to the light emitting units 104a and the light emitting units 104b when viewed along the top view direction TD.

The light shielding layer 136 and/or the light shielding layer 138 may, for example, include a light shielding material, the same material as that of the color filter 106, or other suitable materials. In some embodiments, the light shielding layer 136 and the light shielding layer 138 may be formed by patterning the same layer of the light shielding material using a gray-tone mask or a half-tone mask, or formed by different processes respectively, but not limited thereto. In some embodiments, an area of one of the openings OP8 may be slightly greater than a size of one of the light emitting units 104 when viewed along the top view direction TD. In some embodiments, a reflective layer may be disposed on the blocks 138a to improve the light utilization of the light emitting units 104. In some embodiments, while the light emitting units 104 may be disposed in the openings OP8 through fluid, one of the blocks 138a may be used to confine the corresponding light emitting unit 104 in the corresponding opening OP8, so as to achieve the disposition of the light emitting units 104. The method for disposing the light emitting units 104 of the present disclosure is not limited to the mentioned above. In some embodiments, when the light emitting units 104 are disposed in different methods, the electronic device 1 may not include the light shielding layer 136, but not limited thereto.

As shown in FIG. 1, the conductive layer 140 may be disposed on the circuit layer 122 and include a plurality of traces E9 and a plurality of traces E10, in which the traces E9 and the traces E10 are separated and electrically insulated from each other. One end of one of the light emitting units 104 may be electrically connected to the corresponding connecting electrode E7 through one of the traces E9, so that the light emitting unit 104 may be electrically connected to the electrode E2 of the corresponding capacitor 125. Another end of the light emitting unit 104 may be electrically connected to the corresponding connecting electrode E8 through one of the traces E10, such that the light emitting unit 104 may be electrically connected the drain(source) region SD2 of the corresponding driving element 124a. In the embodiment of FIG. 1, one of the traces E9 and the corresponding trace E10 may respectively extend from the corresponding opening OP8 to the outside of the corresponding block 138a through the upper surface of the corresponding block 138a, but not limited thereto.

In some embodiments, as shown in FIG. 1, the conductive layer 140 may optionally further include a plurality of dummy electrodes E11, and the electronic device 1 may further include a plurality of insulating blocks 142, in which each insulating block 142 may be disposed between the corresponding dummy electrode E11 and the corresponding light emitting unit 104, but not limited thereto. In this case, a sidewall and a lower surface of one of the insulating blocks 142 may have an included angle greater than 90 degrees. For example, one of the insulating blocks 142 may have an inverted trapezoidal cross-sectional shape. Accordingly, when the conductive layer 140 is formed, the conductive layer 140 is not easy to be formed on the sidewall of the insulating block 142. For this reason, as viewed along the top view direction TD, one of the dummy electrodes E11 located between one of the traces E9 and the corresponding trace E10 may be separated from the trace E9 and the trace E10, so as to achieve the electrical insulation between the traces E9 and the traces E10. Through the inverted trapezoidal insulating blocks 142, the patterning processes on the light emitting units 104 may be reduced, thereby saving manufacturing cost or reducing process complexity.

In the embodiment of FIG. 1, the electronic device 1 may optionally include an encapsulation layer 144 disposed between the light emitting units 104 and the color filter 106. For example, the encapsulation layer 144 may be disposed in the openings OP7 and the openings OP8, so that the encapsulation layer 144 may be disposed on the light emitting units 104 and the conductive layer 140 to protect the light emitting units 104 and the conductive layer 140. In some embodiments, the encapsulation layer 144 may be disposed on the upper surface of the light shielding layer 138, or the upper surface of the encapsulation layer 144 may be lower than the upper surface of the light shielding layer 138, but not limited thereto. In some embodiments, as shown in FIG. 1, the upper surface of the light shielding layer 136 may be higher than the upper surface of the encapsulation layer 144, so that the light shielding layer 136 may divide the encapsulation layer 144 into a plurality of blocks, but not limited thereto. In some embodiments, the color filter 106 may be disposed in the opening OP7, but not limited thereto.

In the embodiment of FIG. 1, the electronic device 1 may optionally include an insulating layer 146 disposed on the color filter 106. The insulating layer 146 may have a flat upper surface, for example, to facilitate forming the light shielding layer 114 and the wavelength conversion layers 108 with good quality. The insulating layer 146 may, for example, include a filling material, such as a transparent resin or other suitable material. In some embodiments, the insulating layer 146 may include a functional layer (e.g., a functional layer 178 shown in FIG. 11) to increase light emitting brightness of the light L2, the light L4 and the light L6. The detailed description of the functional layer 178 may refer to the embodiment of FIG. 11.

In some embodiments, as shown in FIG. 1, the electronic device 1 may further optionally include a buffer layer 148 disposed between the substrate 102 and the circuit layer 122. The buffer layer 148 may, for example, be used to block moisture, oxygen or ions from entering the electronic device 1. The buffer layer 148 may be a single-layer structure or a multi-layer structure, and a material of the buffer layer 148 may include, for example, silicon nitride, silicon oxide, silicon oxynitride, aluminum oxide, resin, other suitable materials, or a combination thereof.

The electronic device of the present disclosure is not limited to the above-mentioned embodiments and may have different embodiments or variant embodiments. In order to simplify the description, different embodiments and variant embodiments hereinafter will be denoted by the same reference numerals as the same elements in the first embodiment. In order to easily compare the differences between the first embodiment and the different embodiments or the variant embodiments, the differences in the different embodiments and the variant embodiments will be described below, and same parts will not be repeated.

FIG. 2 is a schematic cross-sectional view illustrating an electronic device according to a second embodiment of the present disclosure. As shown in FIG. 2, the electronic device 2 of this embodiment differs from one of the electronic devices 1 shown in FIG. 1 in that the color filter 106 may be used as the encapsulation layer and disposed in the openings OP7 and the openings OP8, and the color filter 106 may be disposed on the light emitting units 104 and the conductive layer 140 for protecting the light emitting units 104 and the conductive layer 140. Accordingly, the electronic device 2 may not include the encapsulation layer 144 shown in FIG. 1. In some embodiments, the light emitting units 104 may generate light of the same color, and for example, the light emitting unit 104a, the light emitting unit 104b and the light emitting unit 104c may be blue light sources, but not limited thereto. In some embodiments, while the light emitting unit 104a, the light emitting unit 104b and the light emitting unit 104c may be blue light sources, the color filter 106 may be a blue color filter, but not limited thereto. In some embodiments, the height of the upper surface of the color filter 106 may be optionally greater than the height of the upper surface of the light shielding layer 136, so that the color filter 106 may be disposed on the upper surface of the light shielding layer 136, but not limited thereto. In some embodiments, the height of the upper surface of the color filter 106 may be less than the height of the upper surface of the light shielding layer 136 and may fill at least a portion of space between the blocks of the light shielding layer 136. In some embodiments, the color filter 106 may not be disposed on the light emitting unit 104 corresponding to the color filter 110c, so as to improve the brightness of the light emitted by the sub-pixel corresponding to the color filter 110c.

In the embodiment of FIG. 2, the electronic device 2 may optionally not include the wavelength conversion layer 108c and the color filter 110c, but not limited thereto. In this case, since the opening OP6 and the opening OP3 may overlap the light emitting unit 104c, the light L5 may pass through the opening OP6 and the opening OP3 after passing through the color filter 106 to serve as light emitted by a sub-pixel (or a pixel) of the electronic device 1. The insulating layer 120 may for example be disposed in the opening OP3. The insulating layer 116 may for example be disposed in the opening OP6, but not limited thereto. In some embodiments, as viewed along the top view direction TD of the electronic device 2 (or in the top view of the electronic device 2), the area of the opening OP3 may be different from the area of the opening OP1 and the area of the opening OP2. For example, the area of the opening OP3 may be less than the area of the opening OP1 and the area of the opening OP2, so as to reduce the intensity of ambient light entering the opening OP3. In some embodiments, the electronic device 2 may include the color filter 110c of FIG. 1 or both the wavelength conversion layer 108c and the color filter 110c of FIG. 1, but not limited thereto. Other parts of the electronic device 2 shown in FIG. 2 may be, for example, the same as the electronic device 1 shown in FIG. 1 and thus are not described repeatedly.

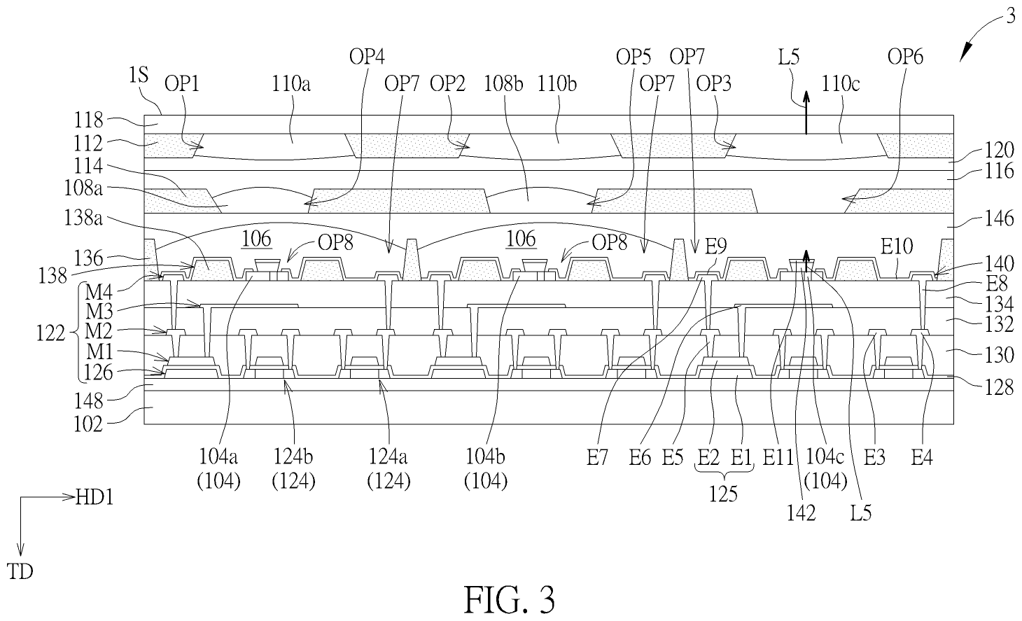

FIG. 3 is a schematic cross-sectional view illustrating an electronic device according to a third embodiment of the present disclosure. As shown in FIG. 3, the color filter 106 of the electronic device 3 of this embodiment may also be used as the encapsulation layer and disposed in the openings OP7 and the openings OP8, and the color filter 106 may be disposed on the light emitting units 104 and the conductive layer 140. The color filter 106 may be formed by a dripping method, so that the electronic device 3 may include a plurality of color filters 106 respectively disposed in the corresponding openings OP7. The dripping method may include, for example, an inkjet printing process or other suitable methods. In this case, the light shielding layer 136 may for example be used as a partition wall for the color filters 106, but not limited thereto. The insulating layer 146 may for example be used as a flat layer and have a flat upper surface, which may facilitate formation of the light shielding layer 114 and the wavelength conversion layer (e.g., the wavelength conversion layer 108a and the wavelength conversion layer 108b).

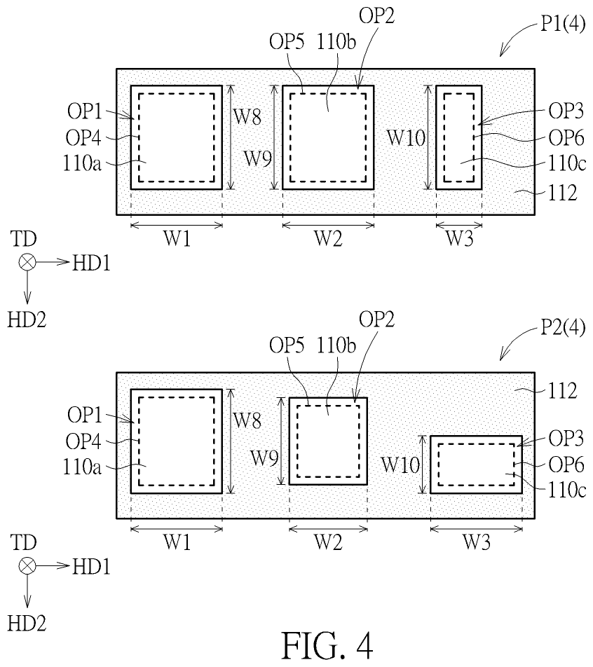

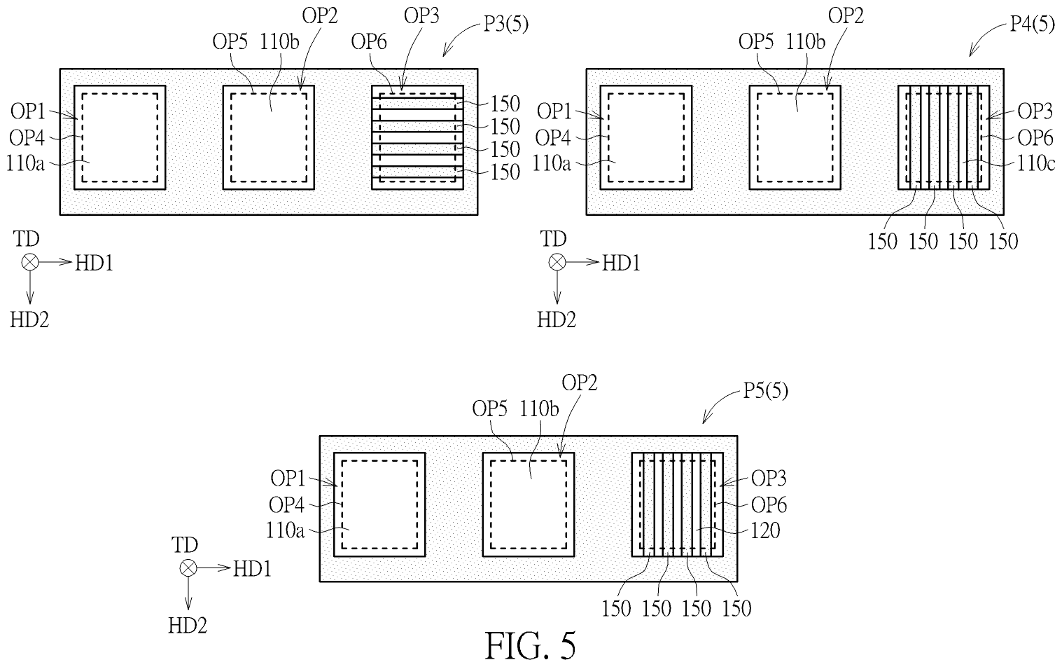

In the embodiment of FIG. 3, the electronic device 3 may include a color filter 110c, and the color filter 106 may not be disposed on the light emitting unit 104 corresponding to the color filter 110c, which may increase the light emitting brightness of the sub-pixel corresponding to the color filter 110c (e.g., the brightness of light such as the light L5), but not limited thereto. For example, when the area of the opening OP3 corresponding to the color filter 110c (e.g., the opening OP3 shown in FIG. 4) is less than the area of the opening OP1 and the area of the opening OP2, or a plurality of light shielding strips (e.g., light shielding strips shown in FIG. 5) are disposed in the opening OP3, the brightness of the light L5 may be improved by not disposing the color filter 106 while reducing the interference of ambient light. In this case, the insulating layer 146 may be disposed in the opening OP7 corresponding to the light emitting unit 104c. In some embodiments, when the electronic device 3 does not include the wavelength conversion layer 108c of FIG. 1, the electronic device 3 may not include the color filter 110c. In some embodiments, the electronic device 3 may include the color filter 106 disposed in the opening OP7 corresponding to the light emitting unit 104c, so as to reduce brightness of reflected light in the region of the opening OP7 corresponding to the light emitting unit 104c. In some embodiments, the electronic device 3 may optionally include or not include the wavelength conversion layer 108c. Other parts of the electronic device 3 shown in FIG. 3 may, for example, be the same as the electronic device 1 shown in FIG. 1 or the electronic device 2 shown in FIG. 2 and thus are not described repeatedly.

FIG. 4 is a schematic top view illustrating a part of an electronic device according to a fourth embodiment of the present disclosure. As shown in an upper portion P1 and a lower portion P2 of FIG. 4, when viewed along the top view direction TD, the area of the opening OP3 of the electronic device 4 may be less than the area of the opening OP1 and the area of the opening OP2, so as to reduce the intensity of the ambient light (e.g., the light L7, etc.) entering the color filter 110c. It should be noted that, since the color of the color filter 110c is similar to or the same as the color of the color filter 106 shown in FIG. 1, the color filter 110c combined with the color filter 106 may have less effect of reducing the intensity of the ambient light as compared with the case of the ambient light passing through the color filter 110a and the color filter 106 or passing through the color filter 110b and the color filter 106. In this embodiment, by reducing the area of the opening OP3 corresponding to the color filter 110c, the intensity of the ambient light may be reduced. In some embodiments, the pixel or sub-pixel corresponding to the opening OP3 may be designed in the following manner. For example, while the light emitting unit 104c may be a blue light source, the color filter 106 may be a blue color filter, and the color filter 110c may be a blue color filter without providing the wavelength conversion layer 108c, but not limited thereto.

In the upper portion P1 of FIG. 4, the width W3 of the opening OP3 may be less than the width W1 of the opening OP1 and/or the width W2 of the opening OP2. The width W10 of the opening OP3 in the horizontal direction HD2 may be, for example, the same as or less than the width W8 of the opening OP1 in the horizontal direction HD2 and/or the width W9 of the opening OP2 in the horizontal direction HD2. The horizontal direction HD2 may be a direction perpendicular to the top view direction TD and different from the horizontal direction HD1, and for example, may be a direction perpendicular to the horizontal direction HD1. As shown in the lower portion P2 of FIG. 4, for example, the width W3 of the opening OP3 may be the same as the width W1 of the opening OP1 and/or the width W2 of the opening OP2, and the width W10 of the opening OP3 may be less than the width W8 of the opening OP1 and/or the width W9 of the opening OP2, but not limited thereto. In some embodiments, as shown in FIG. 4, in the top view direction TD, the area of the opening OP1 may be different from the area of the opening OP2, but not limited thereto. Other parts of the electronic device 4 shown in FIG. 4 may, for example, use corresponding parts of the electronic device 1 shown in FIG. 1 and thus be not redundantly described. In FIG. 4, the opening OP1, the opening OP2 and the opening OP3 shown in the upper portion P1 and/or the opening OP1, the opening OP2 and the opening OP3 shown in the lower portion P2 may be applied to any one of the above or following embodiments.

FIG. 5 is a schematic top view illustrating a part of an electronic device according to a fifth embodiment of the present disclosure. As shown in an upper left portion P3, an upper right portion P4 and a lower portion P5 of FIG. 5, the electronic device 5 may further include a plurality of light shielding strips 150 disposed in the opening OP3 in the top view direction TD and used for reducing the intensity of ambient light (e.g., the light L7) entering the color filter 110c. The light shielding strips 150 may, for example, include a light shielding material, at least two filter materials capable of blocking passage of light, or a combination thereof. In the embodiment of FIG. 5, in the top view direction TD, the area of the opening OP1, the area of the opening OP2 and the area of the opening OP3 may be the same as each other, but not limited thereto. In some embodiments, at least two of the opening OP1, the opening OP2 and the opening OP3 may have different areas.

In the upper left portion P3 of FIG. 5, the light shielding strips 150 may extend along an arranging direction of the color filter 110a, the color filter 110b and the color filter 110c (e.g., the horizontal direction HD1), but not limited thereto. In the upper right portion P4 of FIG. 5, an extending direction of the light shielding strips 150 may, for example, be different from the arranging direction of the color filter 110a, the color filter 110b and the color filter 110c (e.g., the horizontal direction HD1). The extending direction of the light shielding strips 150 may, for example, be a horizontal direction HD2, but not limited thereto. In some embodiments, the pixel or sub-pixel corresponding to the light shielding strips 150 may be designed in the following manner. For example, while the light emitting unit 104c may be a blue light source, the color filter 106 may be a blue color filter, and the color filter 110c may be a blue color filter without providing the wavelength conversion layer 108c, but not limited thereto. In some embodiments, the pixel or sub-pixel corresponding to the light shielding strips 150 may be designed in the following manner. For example, while the light emitting unit 104c may be a blue light source, the color filter 106 may be a blue color filter, and the color filter 110c may be a blue color filter with providing the wavelength conversion layer 108c, but not limited thereto. In the lower portion P5 of FIG. 5, the color filter 110c may not be disposed in the opening OP3, and when the area of the opening OP3 is the same as the area of the opening OP1, the interference of the ambient light (e.g., the light L7 etc.) may be reduced by disposing the light shielding strips 150 in the opening OP3. In some embodiments, the electronic device 5 may not include the wavelength conversion layer 108c or not include both the color filter 110c and the wavelength conversion layer 108c. Other parts of the electronic device 5 shown in FIG. 5 may, for example, use the corresponding parts of the electronic device 1 shown in FIG. 1 and/or the opening OP1, the opening OP2 and the opening OP3 shown in FIG. 4 and thus are not redundantly described. The light shielding strips 150 of FIG. 5 may be used in any one of the above or following embodiments.

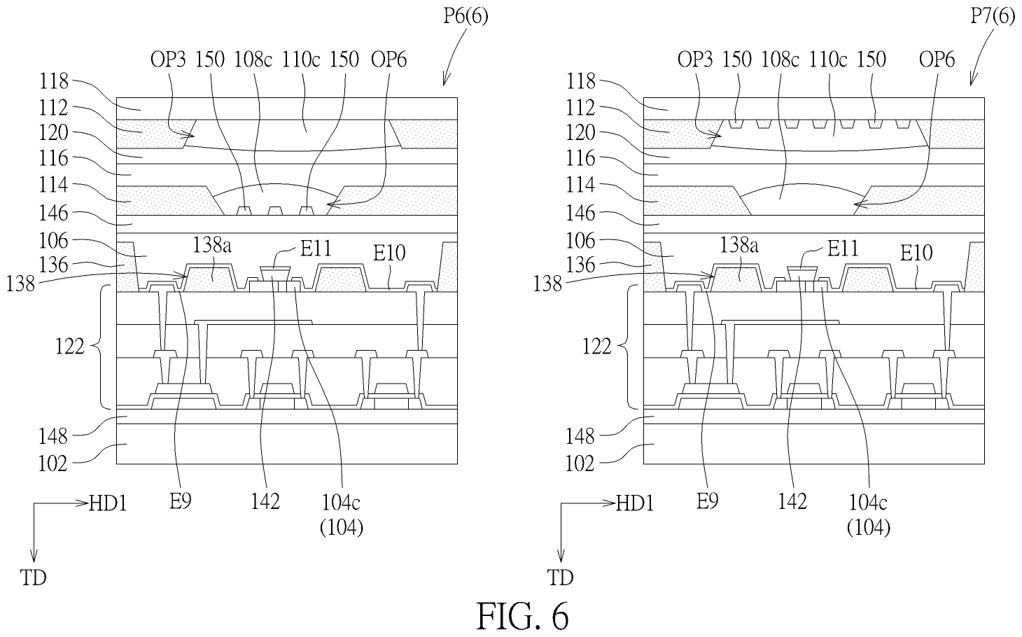

FIG. 6 is a schematic cross-sectional view illustrating apart of an electronic device according to a sixth embodiment of the present disclosure. In order to clearly show the light shielding strips, FIG. 6 does not show the parts of the electronic device corresponding to the color filter 110a and the color filter 110b, but not limited thereto. As shown in a left portion P6 and a right portion P7 of FIG. 6, the light shielding strips 150 of the electronic device 6 may be disposed on the color filter 106. In the left portion P6 of FIG. 6, the light shielding strips 150 may be disposed in the opening OP6. The light shielding strips 150 and the light shielding layer 114 may, for example, include the same light shielding material, or may be formed by the same process using a grayscale mask or a halftone mask or formed of the same layer. In the right portion P7 of FIG. 6, the light shielding strips 150 may be disposed in the opening OP3. For example, the light shielding strips 150 and the light shielding layer 112 may include the same light shielding material, or may be formed by the same process using a gray-scale mask or a halftone mask or formed of the same layer. In some embodiments, the electronic device 6 in the left portion P6 and the right portion P7 of FIG. 6 may not include the wavelength conversion layer 108c or not include both the color filter 110c and the wavelength conversion layer 108c. Other parts of the electronic device 6 shown in FIG. 6 may, for example, use the corresponding parts of the electronic device in any one of the above or following embodiments and thus not be described repeatedly. The light shielding strips 150 of FIG. 6 may be used in any one of the above or the following embodiments.

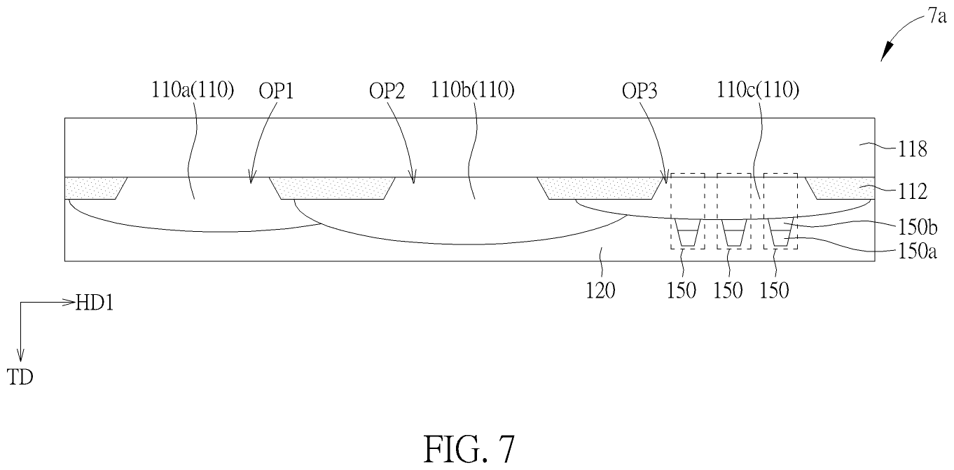

FIG. 7 is a schematic cross-sectional view illustrating an electronic device according to a seventh embodiment of the present disclosure. In order to clearly show the light shielding strips 150 and the color filter 110, elements under the insulating layer 120 are omitted in FIG. 7, but not limited thereto. As shown in FIG. 7, the light shielding strips 150 of the electronic device 7a may include a stack of color filter materials of different colors. Specifically, one of the light shielding strips 150 may include a color filter block 150a, a color filter block 150b and a portion of the color filter 110c overlapped with the color filter block 150a in the top view direction TD stacked under substrate 118 along the top view direction TD. In the embodiment of FIG. 7, the color filter block 150a and the color filter 110a may have the same color, and the color filter block 150b and the color filter 110b may have the same color, but not limited thereto. The color filter block 150b and the color filter 110b may, for example, be formed of the same color filter layer. The color filter block 150a and the color filter 110a may, for example, be formed of the same color filter layer. In some embodiments, the color filter 110c may be blue, the color filter 110b may be green, and the color filter 110a may be red. In some embodiments, the color filter block 150a may be green, and the color filter block 150b may be red, but not limited thereto. In some embodiments, the color filter block 150a may be red, and the color filter block 150b may be green, but not limited thereto. In some embodiments, the color of the color filter block 150a and the color of the color filter block 150b may respectively be green and blue or blue and green, but not limited thereto. In some embodiments, the color of the color filter block 150a and the color of the color filter block 150b may respectively be red and blue or blue and red, but not limited thereto. In the embodiment of FIG. 7, the color filter 110c, the color filter 110b, and the color filter 110a may be formed in sequence, so that the color filter 110c, the color filter block 150b and the color filter 150a may be sequentially stacked under the substrate 118, but not limited thereto. In some embodiments, the stacking order of the color filter block 150a, the color filter block 150b and the color filter 110c may be adjusted for example according to the forming order of the color filter 110a, the color filter 110b and the color filter 110c, but not limited thereto. In some embodiments, one of the light shielding strips 150 of FIG. 7 may not include one of the color filter block 150a and the color filter block 150b. In some embodiments, the color filter block 150a and the color filter 110a may have different colors, and/or the color filter block 150b and the color filter 110b may have different colors. Other parts of the electronic device 7 shown in FIG. 7 may, for example, use the corresponding parts of the electronic device in any one of the above or following embodiments and thus not be described repeatedly. The light shielding strips 150 of FIG. 7 may be used in anyone of the above or following embodiments. In some embodiments, one of the light shielding strips 150 may include a stack (not shown) of color filter materials of three different colors (e.g., red, green, blue, etc.), but not limited thereto.

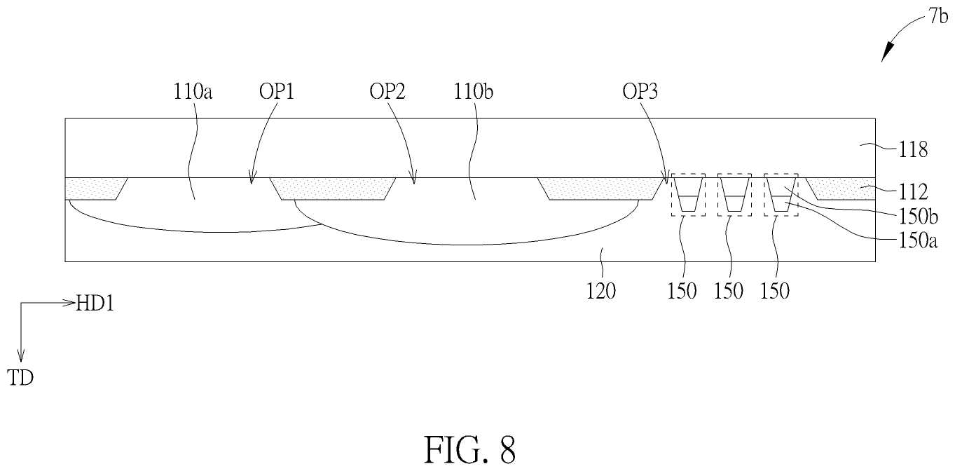

FIG. 8 is a schematic cross-sectional view illustrating an electronic device according to a variant embodiment of the seventh embodiment of the present disclosure. In order to clearly illustrate the light shielding strips 150 and the color filter 110, elements under the insulating layer 120 are omitted in FIG. 8, but not limited thereto. As shown in FIG. 8, the electronic device 7b of this variant embodiment differs from one of the electronic devices 7a of FIG. 7 in that the electronic device 7b may not have the color filter 110c in the opening OP3. In this case, one of the light shielding strips 150 may include the color filter block 150a and the color filter block 150b stacked under the substrate 118. In some embodiments, the color filter 110b may be green, and the color filter 110a may be red. In some embodiments, the color filter block 150a may be green, and the color filter block 150b may be red, but not limited thereto. In some embodiments, the color filter block 150a may be red, and the color filter block 150b may be green, but not limited thereto. In some embodiments, the stacking order of the color filter blocks 150a and the color filter blocks 150b may be adjusted for example according to the forming order of the color filter 110a and the color filter 110b, but not limited thereto. Other parts of the electronic device 7b shown in FIG. 8 may, for example, use the corresponding parts of the electronic device in any one of the above or following embodiments and thus not be described repeatedly. The light shielding strips 150 of FIG. 8 may be applied to any one of the above or following embodiments. In some embodiments, one of the light shielding strips 150 may include a stack (not shown) of color filter materials of three different colors (e.g., red, green, blue, etc.), but not limited thereto.

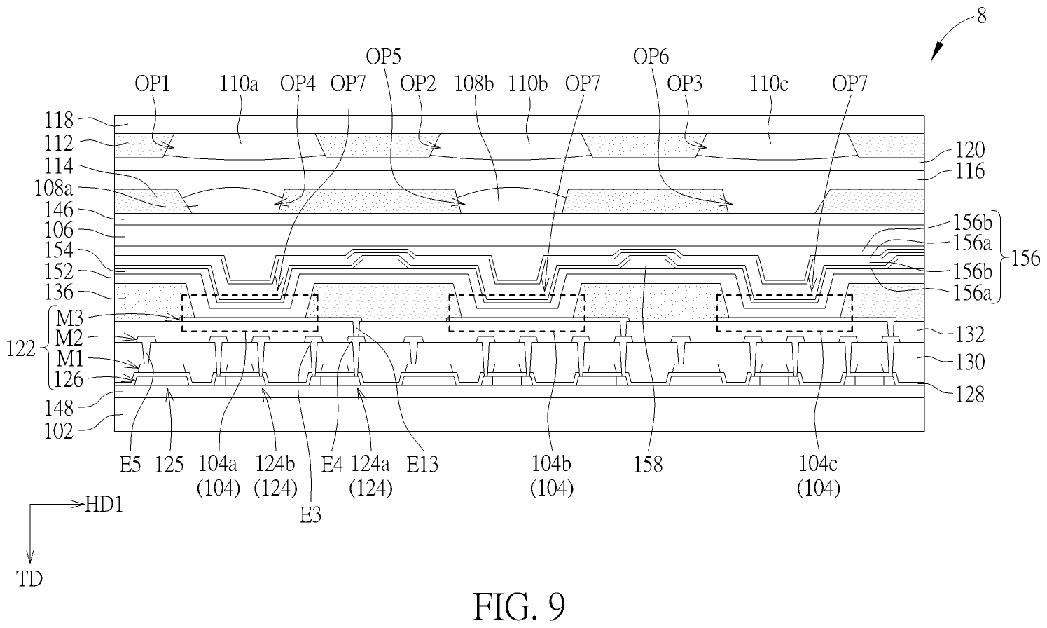

FIG. 9 is a schematic cross-sectional view illustrating an electronic device according to an eighth embodiment of the present disclosure. As shown in FIG. 9, at least one of the light emitting units 104 of the electronic device 8 in this embodiment may be for example the organic light emitting unit. Specifically, the electronic device 8 may include an organic light emitting layer 152 and an electrode layer 154 sequentially disposed on the light shielding layer 136 and the circuit layer 122, and the organic light emitting layer 152 and the electrode layer 154 may be disposed in the openings OP7 of the light shielding layer 136. The metal layer M3 of the circuit layer 122 may include a plurality of electrodes E13 respectively corresponding to the openings OP7 of the light shielding layer 136 in the top view direction TD, so that each electrode E13 and a portion of the organic light emitting layer 152 and a portion of the electrode layer 154 located on the corresponding electrode E13 may form an organic light emitting diode used as one of the light emitting units 104 in this embodiment, but the present disclosure is not limited thereto. In some embodiments, the organic light emitting layer 152 may include a single-layer structure or a multi-layer structure and may not be limited thereto. In some embodiments, the light emitting unit 104 may further include a hole transport layer (HTL), a hole injection layer (HIL), an electron transport layer (ETL), an electron injection layer (EIL) and a charge generation layer (CGL) disposed on the corresponding electrode E13, but not limited thereto. In some embodiments, the light emitting unit 104 may be adjusted according to the requirements, and for example, the light emitting unit 104 may include a plurality of organic light emitting diodes or having different structures. In the embodiment of FIG. 9, the electrodes E13 may be electrically connected to the driving elements 124a through the corresponding through holes of the insulating layer 132 and the corresponding electrodes E4 respectively, but not limited thereto.

In the embodiment of FIG. 9, the electronic device 8 may include a protection layer 156 disposed on the electrode layer 154, and the protection layer 156 may replace the encapsulation layer 144 of FIG. 1. The protection layer 156 may, for example, include a stack of an inorganic material layer 156a, an organic material layer 156b, another inorganic material layer 156a and another organic material layer 156b to reduce penetration of moisture or oxygen. The stack of the protection layer 156 is not limited to that shown in FIG. 9 and may at least include a stack of the inorganic material layer 156a, the organic material layer 156b and the another inorganic material layer 156a. For example, the inorganic material layers 156a may include silicon nitride, silicon oxide, silicon oxynitride, aluminum oxide, or other suitable protecting materials, or any combination of the above inorganic materials, but not limited thereto. The organic material layers 156b may include resin, but not limited thereto. In some embodiments, the protection layer 156 may be formed of the single inorganic material layer 156a or a stack of multiple inorganic material layers 156a. In some embodiments, the color filter 106 may for example replace one of the organic material layers 156b of the protection layer 156 to be included in the protection layer 156.

In some embodiments, as shown in FIG. 9, the electronic device 8 may optionally include an auxiliary electrode 158 used to reduce a difference in resistance between the electrode layer 154 of one of the light emitting units 104 and an external voltage source or between the electrode layer 154 and a peripheral circuit. For example, the auxiliary electrode 158 may be disposed between the electrode layer 154 and the protection layer 156 and be overlapped with the light shielding layer 136. A material of the auxiliary electrode 158 may include magnesium-silver layer, nano-silver paste, aluminum, copper or other suitable conductive materials. In some embodiments, the auxiliary electrode 158 and the electrode layer 154 may include the same material, but not limited thereto. Other parts of the electronic device 8 shown in FIG. 9 may, for example, use the corresponding parts of the electronic device in any one of the above or following embodiments and thus not be described repeatedly. The organic light emitting diode, the protection layer 156 and/or the auxiliary electrode 158 of FIG. 9 may be applied to any one of the above or following embodiments.

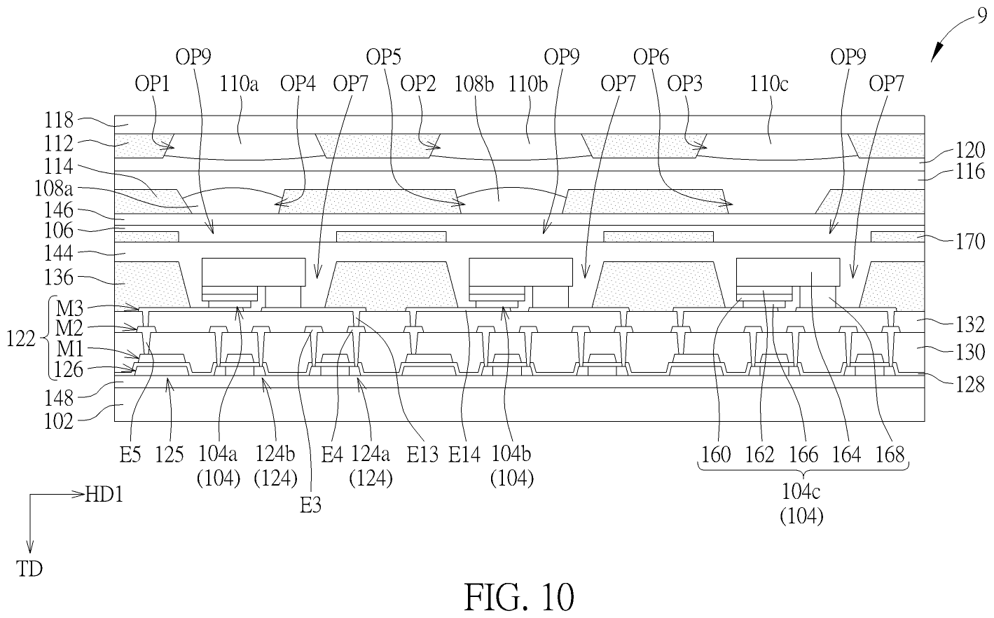

FIG. 10 is a schematic cross-sectional view illustrating an electronic device according to a ninth embodiment of the present disclosure. As shown in FIG. 10, at least one of the light emitting units 104 of the electronic device 9 may be for example the inorganic light emitting unit, such as the micro LED. Specifically, one of the light emitting units 104 may include a semiconductor layer 160, a light emitting layer 162 and a semiconductor layer 164 sequentially stacked along the top view direction TD, and each light emitting unit 104 may be disposed in the opening OP7 of the light shielding layer 136. In some embodiments, the semiconductor layer 160 and the semiconductor layer 164 may be N-type and P-type, respectively, or vice versa. One of the light emitting units 104 may further include a pad 166 disposed under the semiconductor layer 160 and a pad 168 disposed under the semiconductor layer 164. In addition, the metal layer M3 of the circuit layer 122 may include a plurality of electrodes E13 and a plurality of electrodes E14, and each opening OP7 of the light shielding layer 136 may expose one of electrodes E13 and one of the electrodes E14. Accordingly, the pad 166 and the pad 168 of the light emitting unit 104 may be electrically connected to the corresponding electrode E14 and the corresponding electrode E13 so as to be electrically connected to the corresponding capacitor 125 and the corresponding driving element 124a, respectively. The connecting manner of the light emitting unit 104 to the corresponding capacitor 125 and the corresponding driving element 124a of the present disclosure is not limited to the mentioned above. In addition, in FIG. 9, the encapsulation layer 144 may for example be disposed on the light emitting units 104 and the light shielding layer 136, but not limited thereto.

In some embodiments, as shown in FIG. 10, the electronic device 9 may optionally further include alight shielding layer 170 disposed between the encapsulation layer 144 and the color filter 106 and used to reduce light generated by one of the light emitting units 104 from entering non-corresponding openings to reduce or avoid light leakage. The light shielding layer 170 may have a plurality of openings OP9 corresponding to the openings OP7 of the light shielding layer 136 in the top view direction TD, respectively. Other parts of the electronic device 9 shown in FIG. 10 may, for example, use the corresponding parts of the electronic device in any one of the above or following embodiments and thus not be described repeatedly. The inorganic light emitting diode, the encapsulation layer 144 and/or the light shielding layer 170 of FIG. 10 may be applied to any one of the above or following embodiments.

FIG. 11 is a schematic cross-sectional view illustrating an electronic device according to a tenth embodiment of the present disclosure. As shown in FIG. 11, the wavelength conversion layers 108 and the light shielding layer 114 of the electronic device 10 may be formed under the color filters 110 and the light shielding layer 112. In the embodiment of FIG. 11, the insulating layer 146 of the electronic device 10 may include an adhesive layer 182 disposed between the light shielding layer 114 and the color filter 106 and used for bonding the substrate 118 to the substrate 102. In some embodiments, the adhesive layer 182 may be disposed between the wavelength conversion layers 108 and the color filters 110. In some embodiments, the electronic device 10 may not include the wavelength conversion layer 108c or not include both the color filter 110c and the wavelength conversion layer 108c.

In some embodiments, the electronic device 10 may optionally include a functional layer 172 disposed between the wavelength conversion layers 108 and the color filters 110. When the wavelength conversion layers 108 and the light shielding layer 114 are formed under the color filters 110 and the light shielding layer 112, the functional layer 172 may replace the insulating layer 116 and the insulating layer 120 of FIG. 1, for example. The functional layer 172 may, for example, allow the light generated by the wavelength conversion layer 108a, the wavelength conversion layer 108b and the wavelength conversion layer 108c to pass through and reflect the light generated by the light emitting units 104, which enhances the purity of light emitted by the corresponding wavelength conversion layer 108a, the corresponding wavelength conversion layer 108b and the corresponding wavelength conversion layer 108c. In some embodiments, when the color of the light generated by the wavelength conversion layer 108c is the same as the color of the light generated by the light emitting units 104, the functional layer 172 may not cover the opening OP6 in the top view direction TD. In some embodiments, the functional layer 172 may be disposed between the wavelength conversion layers 108 and the color filter 106.

In the embodiment of FIG. 11, the insulating layer 146 of the electronic device 10 may further include an encapsulation layer 174, a planarization layer 176 and a functional layer 178 sequentially disposed under the light shielding layer 114 and the wavelength conversion layers 108. A material of the encapsulation layer 174 may be, for example, the same as or similar to the insulating layer 120, but not limited thereto. The planarization layer 176 may have a flat lower surface to facilitate the formation of the functional layer 178. The functional layer 178 may, for example, allow the light generated by the light emitting units 104 to pass through and reflect the light generated by the wavelength conversion layer 108a, the wavelength conversion layer 108b and the wavelength conversion layer 108c. In some embodiments, when the color of the light generated by the wavelength conversion layer 108c is the same as the color of the light generated by the light emitting units 104, the functional layer 178 may not cover the opening OP6 in the top view direction TD. The functional layer 172 and the functional layer 178 may be, for example, a Bragg multilayer film composed of multiple layers of different refractive indices stacked alternately, and not limited thereto. In some embodiments, a material of the functional layer 172 and/or a material of the functional layer 178 may include, for example, fluoride, polymer or nanocoating layer to facilitate the formation of the wavelength conversion layer on the functional layer 172 or the functional layer 178, but not limited thereto. In some embodiments, the insulating layer 146 of the electronic device 10 may include a cap layer 184 (or an index matching layer) disposed between the color filter 106 and the adhesive layer 182, but not limited thereto. In some embodiments, when the functional layer 178, the light shielding layer 114, and the wavelength conversion layers 108 are formed on the color filter 106, the electronic device 10 may not include the capping layer 184.

In some embodiments, the functional layer 178, the light shielding layer 114 and the wavelength conversion layers 108 may be formed on the color filter 106, and the adhesive layer 182 is disposed between the light shielding layer 114 and the light shielding layer 112. In this case, the encapsulation layer 174 may be disposed between the light shielding layer 114 and the adhesive layer 182, but not limited thereto. In some embodiments, the electronic device 10 may include one of the functional layer 172 and the functional layer 178 but not include the other of the functional layer 172 and the functional layer 178.

In the embodiment of FIG. 11, the electronic device 10 may optionally further include an insulating layer 180 disposed between the encapsulation layer 144 and the color filter 106, and used to improve adhesion between the color filter 106 and the encapsulation layer 144. The insulating layer 180 may include, for example, an inorganic insulating material.

In the embodiment of FIG. 11, the light emitting units 104 may include for example the inorganic light emitting diodes. In some embodiments, the light emitting units 104 may include the organic light emitting diodes. In some embodiments, the encapsulation layer 144 may be replaced with the protection layer 156 shown in FIG. 9, but not limited thereto. Other parts of the electronic device 10 shown in FIG. 11 may for example use the corresponding parts of the electronic device in any one of the above or following embodiments and thus not be described repeatedly. The forming methods of the functional layer 172, the functional layer 178, the insulating layer 180, the insulating layer 146 and/or the light shielding layer 114 and the wavelength conversion layer in FIG. 11 may be applied to any one of the above or following embodiments.

In summary, in the electronic devices of the present disclosure, since the color of the color filter disposed on the wavelength conversion layer may be different from the color of the color filter disposed between the wavelength conversion layer and the light emitting units, the color filters may absorb light of different colors respectively to have complementary light absorption properties. Accordingly, the interference of the ambient light on the image displayed by the electronic device may be reduced, and/or the quality of the image may be improved.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate;
a first light emitting unit disposed on the substrate and configured to emit a first light;
a first color filter disposed on the first light emitting unit;
a first wavelength conversion layer disposed on the first color filter; and
a second color filter disposed on the first wavelength conversion layer;
wherein the first light passes through the first color filter, the first wavelength conversion layer converts the first light into a second light, and the second light passes through the second color filter.

2. The electronic device of claim 1, wherein a thickness of the first color filter is less than a thickness of the second color filter.

3. The electronic device of claim 1, further comprising a second light emitting unit disposed on the substrate, a second wavelength conversion layer disposed on the second light emitting unit, and a third color filter disposed on the second wavelength conversion layer, wherein the first color filter is further disposed between the second wavelength conversion layer and the second light emitting unit.

4. The electronic device of claim 3, wherein the second light emitting unit is configured to emit a third light, the second wavelength conversion layer converts the third light into a fourth light, the fourth light passes through the third color filter and the fourth light is different from the second light in color.

5. The electronic device of claim 4, further comprising a light shielding layer disposed on the first color filter, wherein the light shielding layer has a first opening in which the second color filter is disposed and a second opening in which the third color filter is disposed, and an area of the first opening is different from an area of the second opening in a top view of the electronic device.

6. The electronic device of claim 1, further comprising a third light emitting unit disposed on the substrate and a light shielding layer disposed on the first color filter, wherein the light shielding layer has a first opening in which the second color filter is disposed and a third opening overlapped with third light emitting unit, wherein the third light emitting unit is configured to emit a fifth light, the fifth light passes through the first color filter and the third opening, and an area of the first opening is different from an area of the third opening in a top view of the electronic device.

7. The electronic device of claim 1, wherein the first color filter is a blue color filter.

8. The electronic device of claim 1, wherein the first light emitting unit is an organic light emitting unit.

9. The electronic device of claim 1, wherein the first light emitting unit is an inorganic light emitting unit.
